(19) United States
(12) Patent Application Publication
(10) Pub. No.: US 2012/0261166 A1
(43) Pub. Date: Oct. 18, 2012

(54) PRINTED CIRCUIT BOARD AND METHOD OF MANUFACTURING THE SAME

(75) Inventors: Chang Gun OH, Gyunggi-do (KR); Tae Kyun BAE, Gyunggi-do (KR); Ho Sik PARK, Gyunggi-do (KR)

(73) Assignee: SAMSUNG ELECTRO-MECHANICS CO., LTD., Gyunggi-do (KR)

(21) Appl. No.: 13/189,124

(22) Filed: Jul. 22, 2011

(30) Foreign Application Priority Data
Apr. 15, 2011 (KR) 10-2011-0035218

(51) Int. Cl. H05K 7/20; B05D 3/00; B05D 5/12; H05K 1/11; H05K 3/46

(52) U.S. Cl. 174/252; 174/266; 427/97.2

(57) ABSTRACT

Disclosed herein are a printed circuit board and a method of manufacturing the same. The printed circuit board includes: a base substrate having a via hole for signal transfer and a via hole for heat radiation formed therein and having circuit layers formed on both surfaces thereof, the circuit layers including connection pads; a signal via formed in an inner portion of the via hole for signal transfer by performing a plating process using a conductive metal; and a heat radiation via formed in an inner portion of the via hole for heat radiation by performing a plating process using a conductive metal, wherein the heat radiation via is formed to have a diameter larger than that of the signal via.

### CROSS REFERENCE TO RELATED APPLICATION

This application claims the benefit of Korean Patent Application No. 10-2011-0035218, filed on Apr. 15, 2011, entitled “Printed Circuit Board And Manufacturing Method of The Same” which is hereby incorporated by reference in its entirety into this application.

### BACKGROUND OF THE INVENTION

1. Technical Field

The present invention relates to a printed circuit board and a method of manufacturing the same.

2. Description of the Related Art

In accordance with the recent trend toward complex and multi-function electronic devices, research into a problem of heat generation during the driving of a semiconductor device, which is the core of the electronic device, has been conducted.

Efforts to design a low power semiconductor in terms of the semiconductor device have been made. However, it is difficult to develop the low power semiconductor and it takes a long time to commercialize the low power semiconductor.

Meanwhile, efforts to prevent performance of a semiconductor from being deteriorated by efficiently removing heat generated in the semiconductor using an interposer or a substrate for the semiconductor that are used to mount the semiconductor on a main board have been made. As a typical example, there may be a metal core substrate.

However, the metal core substrate propagates the heat in a horizontal direction thereof and has an outline mainly blocked by an organic layer, such that the heat is not transferred by a pure metal but should pass through an organic insulating material. Therefore, the metal core substrate is not particularly efficient in removing the generated heat.

### SUMMARY OF THE INVENTION

The present invention has been made in an effort to provide a printed circuit board for improving a heat radiation effect, and a method of manufacturing the same.

According to a first preferred embodiment of the present invention, there is provided a printed circuit board including: a base substrate having first and second via holes formed therein and having circuit layers formed on both surfaces thereof, the circuit layers including to connection pads; a first via formed in an inner portion of the first via hole and made of a conductive metal; and a second via formed in an inner portion of the second via hole and including a plurality of plating layers made of a conductive metal, wherein the second via is formed to have a diameter larger than that of the first via.

The first and second via holes may be a via hole for signal transfer and a via hole for heat radiation, respectively, and the first and second vias may be a signal via and a heat radiation via, respectively.

A diameter ratio between the first and second vias may be 1:2.

The base substrate may be a multi-layer substrate having metal layers for inner layer circuits formed in an insulating layer.

When the printed circuit board is a wire bonding type, the connection pads may include a pad for wire bonding and the circuit layer may further includes a pad for chip mounting, and the second via may be formed beneath the pad for chip mounting and the first via may be formed beneath the pad for wire bonding.

When the printed circuit board is a flip chip bonding type, the connection pads may include pads for external connection terminals and the pads for external connection terminals may include a pad for power or ground and a pad for signal input/output, and the second via may be formed beneath the pad for power or ground and the first via may be formed beneath the pad for signal input/output.

The printed circuit board may further include external connection terminals formed on the pads for external connection terminals in order to mount a chip thereon.

The external connection terminal may be a solder ball.

The base substrate may further include a metal layer for heat radiation formed in an inner portion thereof.

According to a second preferred embodiment of the present invention, there is provided a method of manufacturing a printed circuit board, the method including: preparing to a base substrate; forming first and second via holes in the base substrate; forming a first plating layer, the first plating layer having a height lower than that of an upper surface of the base substrate by performing a plating process on the second via hole; and forming a circuit layer including connection pads formed on a second plating layer, a first via, and the base substrate by performing a plating process on a non-plated region of the second via hole, the first via hole, and the base substrate, wherein the second via includes the first and second plating layers and is formed to have a diameter larger than that of the first via.

The first and second via holes may be a via hole for signal transfer and a via hole for heat radiation, respectively, and the first and second vias may be a signal via and a heat radiation via, respectively.

The preparing of the base substrate may include: preparing a carrier member having a seed layer formed on one surface thereof; forming a first circuit layer on the carrier member; and forming an insulating layer on the first circuit layer.

The method may further include removing the carrier member after the forming of the circuit layer including the connection pads.

The preparing of the base substrate may include: preparing a carrier member having a seed layer formed on one surface thereof; forming a first insulating layer on the carrier member; forming a metal layer for heat radiation having an open part on the first insulating layer, the open part being formed at a region at which the first via is to be formed; forming a second insulating layer on the metal layer for heat radiation; and removing the carrier member.

The forming of the first plating layer may include: forming a plating resist on the base substrate, the plating resist having an open part corresponding to the second via hole; filling the second via hole with a conductive metal through the open part so that the conductive metal has a height lower than that of an upper surface of the base substrate; and removing the plating resist.

The open part may be formed to have a diameter smaller than that of the second via hole.

The forming of the circuit layer including the connection pads may include: forming a plating resist having an open part on the base substrate in order to form the circuit layer including the connection pads formed on the second via, the first via, and the base substrate; forming the circuit layer including the connection pads formed on the second via, the first via, and the base substrate by performing a plating process on the open part; and removing the plating resist.

When the printed circuit board is a wire bonding type, the connection pads may include a pad for wire bonding and the circuit layer may further include a pad for chip mounting, and the second via may be formed beneath the pad for chip mounting and the first via may be formed beneath the pad for wire bonding.

When the printed circuit board is a flip chip bonding type, the connection pads may include pads for external connection terminals and the pads for external connection terminals may include a pad for power or ground and a pad for signal input/output, and the second via may be formed beneath the pad for power or ground and the first via may be formed beneath the pad for signal input/output.

The method may further include forming external connection terminals on the pads for external connection terminals in order to mount a chip thereon after the forming of the circuit layer including the connection pads.

### BRIEF DESCRIPTION OF THE DRAWINGS

FIG. 1 is a view showing a printed circuit board according to a first preferred embodiment of the present invention;

FIG. 2 is a view showing a printed circuit board according to a second preferred to embodiment of the present invention;

FIG. 3 is a view showing a printed circuit board according to a third preferred embodiment of the present invention;

FIGS. 4 to 13 are process flowcharts describing a method of manufacturing the printed circuit board of FIG. 1;

FIGS. 14 to 23 are process flowcharts describing a method of manufacturing the printed circuit board of FIG. 2; and

FIGS. 24 to 31 are process flowcharts describing a method of manufacturing the printed circuit board of FIG. 3.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In to the description, the terms “first”, “second”, and so on are used to distinguish one element from another element, and the elements are not defined by the above terms.

Hereinafter, preferred embodiments of the present invention will be described in detail with reference to the accompanying drawings.

### Printed Circuit Board—First Preferred Embodiment

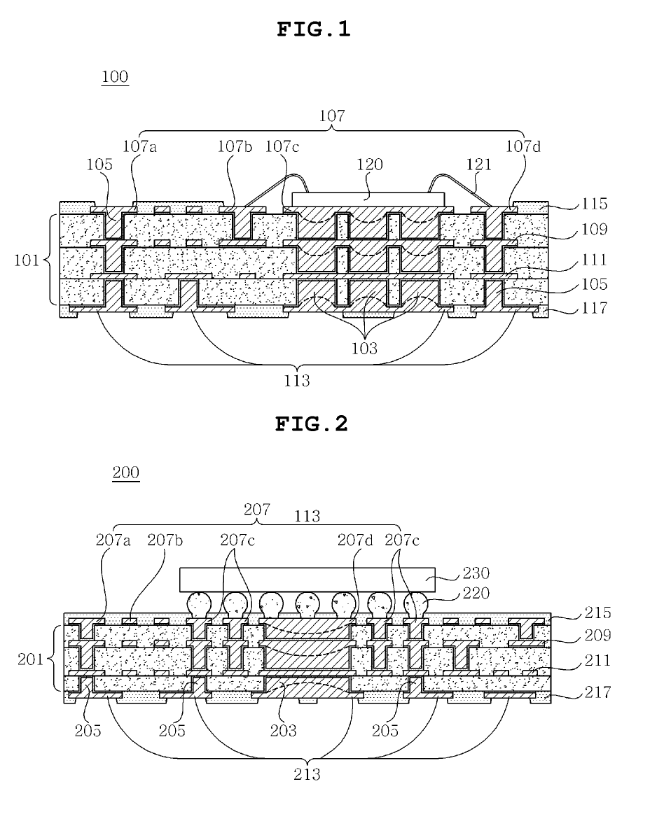

FIG. 1 is a view showing a printed circuit board according to a first preferred embodiment of the present invention. A case in which a printed circuit board is a wire bonding type will be described by way of example.

Referring to FIG. 1, a printed circuit board 100 is configured to include a base substrate having first and second via holes formed therein and having circuit layers 107 and 113 formed on both surfaces thereof, the circuit layers 107 and 113 including connection pads 107a, 107b, 107c, 107d, and 113; a first via 105 formed in an inner portion of the first via hole (not shown) and made of a conductive metal; and a second via 103 formed in an inner portion of the second via hole (not shown) and including a plurality of plating layers made of a conductive metal, wherein the second via 103 is formed to have a diameter larger than that of the first via 105.

Here, the first via 105 and the second via 103 further include electroless metal plating layers formed on inner walls of the via holes.

In addition, the first and second via holes are a via hole for signal transfer and a via hole for heat radiation, respectively, and the first and second vias are a signal via 105 and a heat radiation via 103, respectively.

Hereinafter, for convenience of explanation, the first via hole, the second via hole, the first via, and the second via will be referred to as a via hole for signal transfer, a via hole for heat radiation, a signal via, and a heat radiation via, respectively.

In addition, the heat radiation via 103 may be a cylindrical via having a size larger than that of the signal via 105, and may be an elongated bar shaped via in a length direction of a substrate according to its purpose. That is, the heat radiation via 103 may be implemented to have various shapes according its purpose.

When the printed circuit board 100 is the wire boding type, the connection pad may include a pad 107b for wire bonding, and the circuit layer may further include a pad 107c for chip mounting.

In addition, the heat radiation via 103 may be formed beneath the pad 107c for chip mounting, and the signal via 105 may be formed beneath the pads 107b and 107d for wire bonding.

Here, the circuit layer including the connection pad may be made of any material as long as being used as a conductive metal for a circuit in a circuit board field, preferably, copper in consideration of heat radiation characteristics.

Since a size of the heat radiation via 103 including a diameter is larger than that of the signal via 105, heat generated from a chip may be more efficiently radiated to the outside.

In addition, since the heat radiation via 103 is formed to directly contact the pad 107c for chip mounting, the heat generated from the chip 120 to be mounted on the pad 107c for chip mounting may be efficiently removed. Therefore, the entire performance of the printed circuit board may be improved.

The heat radiation via 103 may be formed to have a larger size of about two times or more than that of the signal via 105, thereby optimizing heat radiation efficiency.

For example, a diameter ratio between the signal via 105 and the heat radiation via 103 may be 1:2; however, it is not limited thereto.

The heat radiation via 103 may be configured of first and second plating layers and may have an interface (a dotted line of FIG. 1) formed between the first and second plating layers. Meanwhile, the heat radiation via 103 may also be configured of at least two plating layers according to the number of plating processes.

Here, as the conductive metal used at the time of performing a plating process, copper used at the time of forming the circuit may be used in consideration of heat radiation characteristics.

For example, since the heat radiation via 103 may have a diameter of 200 μm or more in the present invention, it is difficult to fill the via hole for heat radiation by performing the plating process once. Therefore, the heat radiation via 103 is formed by performing the plating process twice, such that an interface between a primary plating process and a secondary plating process is formed. A method of forming the heat radiation via 103 with relation to this will be described below.

Meanwhile, the via hole for signal transfer and the via hole for heat radiation may be formed by performing laser drilling.

Referring to FIG. 1, the base substrate may be a multi-layer substrate having metal layers 109 and 111 for inner layer circuits formed in the insulating layer.

A design of the metal layers for circuits shown in FIG. 1 is an example and may be changed by an operator, as needed. However, even at this time, the via for heat radiation should be formed to have a size larger than that of the via for signal transfer.

Meanwhile, as the insulating layer, a resin insulating layer may be used. As materials of the resin insulating layer, a thermo-setting resin such as an epoxy resin, a thermo-plastic resin such as a polyimide resin, a resin having a reinforcement material such as a glass fiber or an inorganic filler impregnated in them, for example, a prepreg may be used. In addition, a thermo-setting resin, a photo-setting resin, and the like, may be used. However, the materials of the resin insulating layer are not specifically limited thereto.

Meanwhile, the printed circuit board 100 may include the chip 120 mounted thereon and further include a wire 121 formed in order to electrically connect the pads 107b and 170d for wire bonding to the chip 120.

### Printed Circuit Board—Second Preferred Embodiment

FIG. 2 is a view showing a printed circuit board according to a second preferred to embodiment of the present invention. A case in which a printed circuit board is a flip chip bonding type will be described by way of example.

However, in a second preferred embodiment, a description for the same components as those of the first preferred embodiment will be omitted and a description only for components different therefrom will be provided.

Referring to FIG. 2, a printed circuit board 200 is configured to include a base substrate having a via hole for signal transfer and a via hole for heat radiation formed therein and having circuit layers 207 and 213 formed on both surfaces thereof, the circuit layers 207 and 213 including connection pads 207a, 207c, 707d, and 213; a signal via 205 formed in an inner portion of the via hole for signal transfer (not shown) and made of a conductive metal; and a heat radiation via 203 formed in an inner portion of the via hole for heat radiation (not shown) and including a plurality of plating layers made of a conductive metal, wherein the heat radiation via 203 is formed to have a diameter larger than that of the signal via 205.

When the printed circuit board 200 is the flip chip bonding type, the connection pads 207a, 207c, and 207d may include pads 207c and 207d for external connection terminals, and the pads 207c and 207d for external connection terminals may include a pad 207d for power or ground and a pad 207c for signal input/output.

In addition, the printed circuit board 200 may further include external connection terminals 220 formed on the pads 207c and 207d for external connection terminals in order to mount a chip 230 thereon. Here, the external connection terminal 220 may be a solder ball, as shown in FIG. 2.

In addition, the heat radiation via 203 may be formed beneath the pad 207d for power or ground, and the signal via 205 may be formed beneath the pad 207c for signal input/output.

This is to efficiently remove heat generated from the pad 207d for power or ground that is expected to generate higher heat, as compared to the pad 207c for signal input/output through which a signal is simply input/output. Therefore, it is possible to stably supply power to the printed circuit board and improve a heat radiation effect of the printed circuit board.

A diameter ratio between the signal via 205 and the heat radiation via 203 may be 1:2, thereby making it possible to maximize radiation efficiency.

Referring to FIG. 2, the base substrate may be a multi-layer substrate having metal layers 209 and 211 for inner layer circuits formed in the insulating layer.

In addition, the heat radiation via 203 may be configured of first and second plating layers and may have an interface (a dotted line of FIG. 2) formed between the first and second plating layers.

### Printed Circuit Board—Third Preferred Embodiment

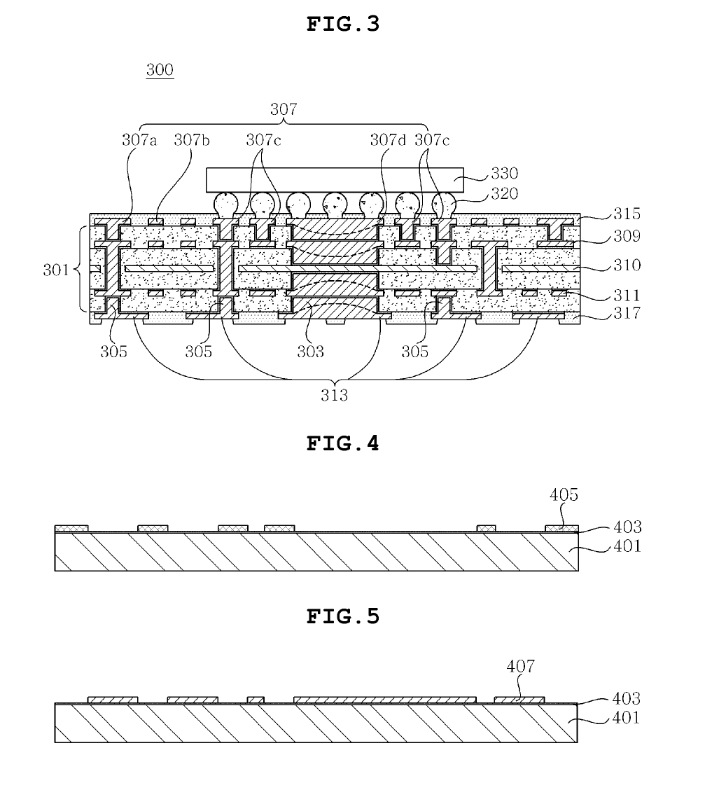

FIG. 3 is a view showing a printed circuit board according to a third preferred embodiment of the present invention. A case in which a printed circuit board is a flip chip bonding type and has a metal layer for heat radiation formed on a base substrate will be described by way of example.

However, in a third preferred embodiment, a description for the same components as those of the first and second preferred embodiments will be omitted and a description only for components different therefrom will be provided.

Referring to FIG. 3, a printed circuit board 300 is configured to include a base substrate having a via hole for signal transfer and a via hole for heat radiation formed therein and having circuit layers 307 and 313 formed on both surfaces thereof, the circuit layers 307 and 313 including connection pads 307a, 307c, 307d, and 313; a signal via 305 formed in an inner portion of the via hole for signal transfer (not shown) and made of a conductive metal; and a heat radiation via 303 formed in an inner portion of the via hole for heat radiation (not shown) and including a plurality of plating layers made of a conductive metal, wherein the heat radiation via 303 is formed to have a diameter larger than that of the signal via 305.

When the printed circuit board 300 is the flip chip bonding type, the connection pads 307a, 307c, and 307d may include pads 307c and 307d for external connection terminals, and the pads 307c and 307d for external connection terminals may include a pad 307d for power or ground and a pad 307c for signal input/output.

In addition, the printed circuit board 300 may further include external connection terminals 320 formed on the pads 307c and 307d for external connection terminals in order to mount a chip 330 thereon.

Further, the heat radiation via 303 may be formed beneath the pad 307d for power or ground, and the signal via 305 may be formed beneath the pad 307c for signal input/output.

Meanwhile, referring to FIG. 3, the base substrate may further include a metal layer 310 for heat radiation formed in an inner portion thereof.

The metal layer 310 for heat radiation is inserted into the base substrate formed of an insulating layer at a central point based on a thickness direction thereof and may perform heat radiation in a horizontal direction as well as in a thickness direction of the heat radiation via, thereby further improving heat radiation characteristics of the printed circuit board 300.

For example, heat generated from the chip 330 is transferred downwardly of the substrate through the heat radiation via 303. Then, when the heat arrives at the metal layer 310 for heat radiation, a portion thereof is transferred horizontally along the metal layer 310 for heat radiation and the other portion thereof is transferred downwardly of the substrate. Therefore, the heat may be transferred more rapidly, as compared to a case in which the heat is simply transferred in a vertical direction of the substrate.

A diameter ratio between the signal via 305 and the heat radiation via 303 may be 1:2, thereby making it possible to maximize radiation efficiency.

Referring to FIG. 3, the base substrate may be a multi-layer substrate having metal layers 309 and 311 for inner layer circuits formed in the insulating layer.

The heat radiation via 303 may be configured of first and second plating layers and may have an interface (a dotted line of FIG. 3) formed between the first and second plating layer.

Although not shown, in addition to the base substrate according to the third preferred embodiment, the wire bonding type of base substrate according to the first preferred embodiment may further include the metal layer for heat radiation formed in an inner portion thereof.

Hereinafter, although reference numerals different from those of the above-mentioned printed circuit boards will be used for convenience of explanation, it will be obvious that components having the same designation perform the same function.

### Method Of Manufacturing Printed Circuit Board—First Preferred Embodiment

FIGS. 4 to 13 are process flowcharts describing a method of manufacturing the printed circuit board of FIG. 1.

First, referring to FIG. 4, a carrier member 401 having a seed layer 403 formed on one surface thereof is prepared, and a plating resist 405 having an open part is formed in order to form a first circuit layer 407.

Here, the plating resist 405 may be a dry film; however, it is not limited thereto.

In addition, as the carrier member 401, a carrier member serving as a support is prepared in order to prevent a printed circuit board from being bent during a process of manufacturing the printed circuit board.

Then, referring to FIG. 5, a plating process is performed on the open part to thereby form the first circuit layer 407.

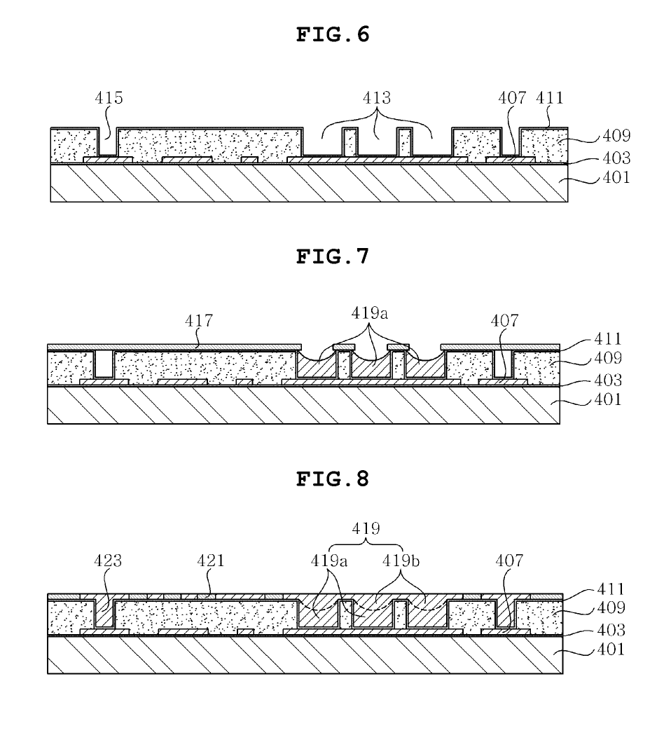

Next, referring to FIG. 6, an insulating layer 409 is formed on the first circuit layer 407 on the carrier member 401, and a via hole 415 for signal transfer and a via hole 413 for heat radiation are formed in the insulating layer 409.

That is, according to the present embodiment, the via hole 415 for signal transfer and to the via hole 413 for heat radiation are formed in a base substrate having the insulating layer 409 formed on the first circuit layer 407.

Here, the insulating layer 409 may have a seed layer 411 formed thereon.

In addition, the via hole 413 for heat radiation may be formed to have a diameter larger than that of the via hole 415 for signal transfer.

Here, the via holes may be drilled by a laser drill.

Thereafter, although not shown, after the via holes are drilled, a desmear process is performed to thereby remove a smear generated due to the drilling of the via hole, and a seed layer for forming patterns may be formed on an inner wall of the via hole 415 for signal transfer and the via hole 413 for heat radiation.

Here, the seed layer may be formed by performing a chemical copper plating process or be formed by performing an electrolytic copper plating process in the case in which there is a margin in a pitch of a circuit to be subsequently formed. In addition, the seed layer may have a thickness of 1 to 5 μm.

Then, referring to FIG. 7, a plating process is performed on the via hole 413 for heat radiation to thereby form a first plating layer 419a having a height lower than that of an upper surface of the insulating layer 409.

Here, as a conductive metal used at the time of performing a plating process, copper used at the time of forming the circuit may be used in consideration of heat radiation characteristics.

More specifically, a plating resist 417 having an open part corresponding to the via hole 413 for heat radiation is formed on the insulating layer 409.

Here, the open part may be formed to have a diameter smaller than that of the via hole 413 for heat radiation.

The open part is formed by applying a photosensitive dry film for forming the circuit over the entire surface of the insulating layer and then selectively opening only the via hole for heat radiation through an exposure and development process. Here, the open part may be formed to have a size smaller than that of the via hole for heat radiation in consideration of alignment of a process of forming a circuit.

If a matching capability is 30 μm and a size of a heat radiation via is 200 μm, the open part of the dry film formed at an upper portion of the via hole for heat radiation may have a size of 140 μm or less in consideration of the matching capability.

Meanwhile, the plating resist 417 may be a dry film; however, it is not limited thereto. The open part of the plating resist 417 may be formed through the exposure and development process; however, it is not limited thereto.

Then, a plating process is performed on the open part using a conductive metal to thereby fill the via hole 413 for heat radiation. Here, the conductive metal is formed to have a height lower than that of the upper surface of the insulating layer 409. For example, when a thickness of the insulating layer is 80 μm, a plating thickness of the heat radiation via may be 60 to 80 μm.

Thereafter, the plating resist 417 is removed.

Then, referring to FIG. 8, a plating process is performed on a non-plated region of the via hole 413 for heat radiation, the via hole 415 for signal transfer, and the insulating layer 409 using a conductive metal to thereby form a second circuit layer including connection pads formed on a second plating layer 419b, a signal via 423, and the insulating layer. That is, a heat radiation via 419 is configured of the first plating layer 419a and the second plating layer 419b.

Here, the heat radiation via 419 may be formed to have a diameter larger than that of the signal via 423 to thereby optimize a heat radiation effect in a region in which heat radiation is required. A diameter ratio between the signal via 423 and the heat radiation via 419 may be 1:2; however, it is not limited thereto. The heat radiation via may have a larger diameter of two times or more than that of the signal via 423.

More specifically, as shown in FIG. 8, a plating resist 421 having an open part is formed on the insulating layer 409 in order to form a circuit layer including the connection pads formed on the heat radiation via 419, the signal via 423, and the insulating layer.

Meanwhile, the plating resist 421 may be a dry film; however, it is not limited thereto. The open part of the plating resist 421 may be formed through the exposure and development process; however, it is not limited thereto.

For example, the plating resist 421 may be formed to have an annular ring shape according to designs of the signal and heat radiation vias and the circuit.

Then, a plating process is performed on the open part using a conductive metal to thereby form the circuit layer including the connection pads formed on the heat radiation via 419, the signal via 423, and the insulating layer 409. Here, the plating process may be performed by a general electroplating method.

Meanwhile, when deviation for each position is seriously generated in a primary plating process and this problem should be solved or when dimples of all vias should be removed, a planarization process through surface polishing may also be performed.

As shown in FIGS. 7 and 8, since the heat radiation via 419 is formed by performing the plating process twice, an interface (a dotted line of FIG. 8) may be formed between the first plating layer 419a by a primary plating process and the second plating layer 419b by a secondary plating process.

Thereafter, the plating resist 421 is removed.

As shown in FIG. 13, when the printed circuit board is a wire bonding type, the connection pad may include a pad for wire bonding and the circuit layer may further include a pad for chip mounting.

In addition, the heat radiation via 419 is formed beneath the pad for chip mounting, and the signal via 423 is formed beneath the pad for wire bonding.

This should also be reflected at the time of the drilling of the above-mentioned via hole 413 for heat radiation and via hole 415 for signal transfer.

The heat radiation via 419 formed to have a size larger than that of the signal via 423 is formed beneath the pad for chip mounting in consideration of heat radiation characteristics, thereby making it possible to rapidly transfer heat generated from a chip to be subsequently mounted downwardly of the printed circuit board.

When there is a via having a large size such as the heat radiation via in the present invention, the via is not filled by a general pattern fill plating process, such that a dimple is generated. In the case in which the dimple is enlarged, it is difficult to form a stack via and a problem is also generated when a via hole is drilled in an upper portion thereof by a laser beam.

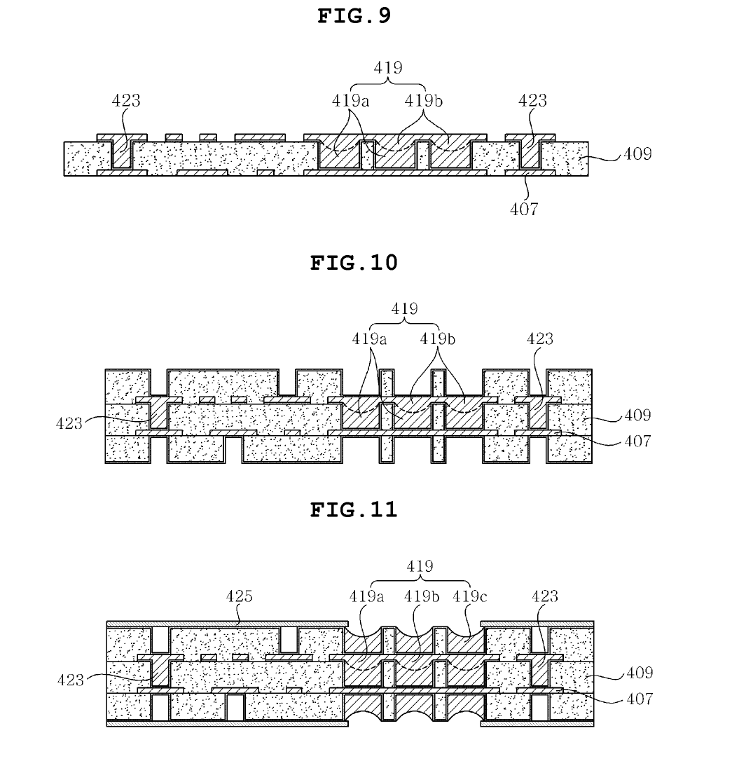

In order to solve these problems, in the present invention, the heat radiation via having a large size is formed by performing the plating process twice, as described above. Next, referring to FIG. 9, the carrier member 401 and the seed layer 403 are removed.

For example, as shown in FIG. 9, the printed circuit board is separated from the carrier member 401 and an exposed seed layer 403 is removed.

The base substrate according to a preferred embodiment of the present invention may be a multi-layer substrate having metal layers for inner layer circuits formed in the insulating layer. Hereinafter, referring to FIGS. 10 to 12, a case in which the base substrate is a four-layer substrate will be described by way of example.

Referring to FIG. 10, insulating layers are formed on upper and lower portions of the insulating layer 409 of the printed circuit board in which the carrier member 401 the seed layer 403 are removed in FIG. 9, and via holes for heat radiation and via holes for signal transfer are drilled in the insulating layers formed on the upper and lower portions of the insulating layer 409.

Here, the via hole for heat radiation may be formed at a position corresponding to the previously formed heat radiation via (for example, a position at which a via connected to the previous heat radiation via is formed) in consideration of heat radiation characteristics.

Then, referring to FIG. 11, a plating process is performed on the via hole for heat radiation using a conductive metal.

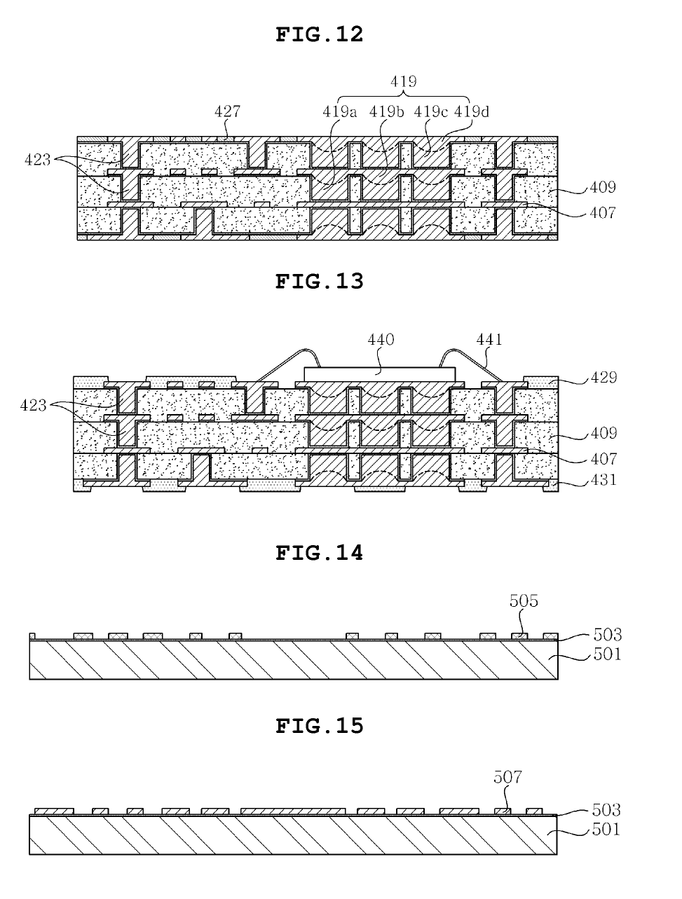

Thereafter, referring to FIG. 12, a plating process is performed on a non-plated region of the via hole for heat radiation, the via hole for signal transfer, and the insulating layer using a conductive metal to thereby form a circuit layer including the connection pads on the heat radiation via 419, the signal via 423, and the insulating layer.

The processes of FIGS. 10 to 12 such as the formation of plating resists 425 and 427, or the like, are the same as those of FIGS. 6 to 8 except that upper or lower circuit layers are formed on the printed circuit board in which the carrier member 401 is removed. Therefore, a detailed description thereof will be omitted.

Meanwhile, as shown in FIGS. 11 and 12, since the heat radiation via 419 is formed by performing the plating process twice, an interface is formed between a first plating layer 419c by a primary plating process and a second plating layer 419d by a second plating process.

Then, as shown in FIG. 13, a process of forming solder resists 429 and 431 on outermost layers of the printed circuit board and a process of treating a surface are performed and a process of mounting a chip 440 on the pad for chip mounting and forming a wire 441 for electrical connection between the pad for wire bonding and the chip 440 is then further performed.

### Method of Manufacturing Printed Circuit Board—Second Preferred Embodiment

FIGS. 14 to 23 are process flowcharts describing a method of manufacturing the printed circuit board of FIG. 2.

However, in a second preferred embodiment, a description for the same components as those of the first preferred embodiment will be omitted and a description only for components different therefrom will be provided.

First, referring to FIG. 14, a carrier member 501 having a seed layer 503 formed on one surface thereof is prepared, and a plating resist 505 having an open part is formed in order to form a first circuit layer 507.

Then, referring to FIG. 15, a plating process is performed on the open part to thereby form the first circuit layer 507.

Next, referring to FIG. 16, an insulating layer 509 is formed on the first circuit layer 507 on the carrier member 501, and a via hole 515 for signal transfer and a via hole 509 for heat radiation 513 are formed in the insulating layer 509.

That is, according to the present embodiment, the via hole 515 for signal transfer and the via hole 513 for heat radiation are formed in a base substrate having the insulating layer 509 formed on the first circuit layer 507.

Here, the via hole 513 for heat radiation may be formed to have a larger diameter of two times or more than that of the via hole 515 for signal transfer.

Then, referring to FIG. 17, a plating process is performed on the via hole 513 for heat radiation to thereby form a first plating layer 519a having a height lower than that of an upper surface of the insulating layer 509.

More specifically, a plating resist 517 having an open part corresponding to the via hole 513 for heat radiation is formed on the insulating layer 509.

Here, the open part may be formed to have a diameter smaller than that of the via hole 513 for heat radiation.

Then, a plating process is performed on the open part using a conductive metal to thereby fill the via hole 513 for heat radiation. Here, the conductive metal is formed to have a height lower than that of the upper surface of the insulating layer 509.

Thereafter, the plating resist 517 is removed.

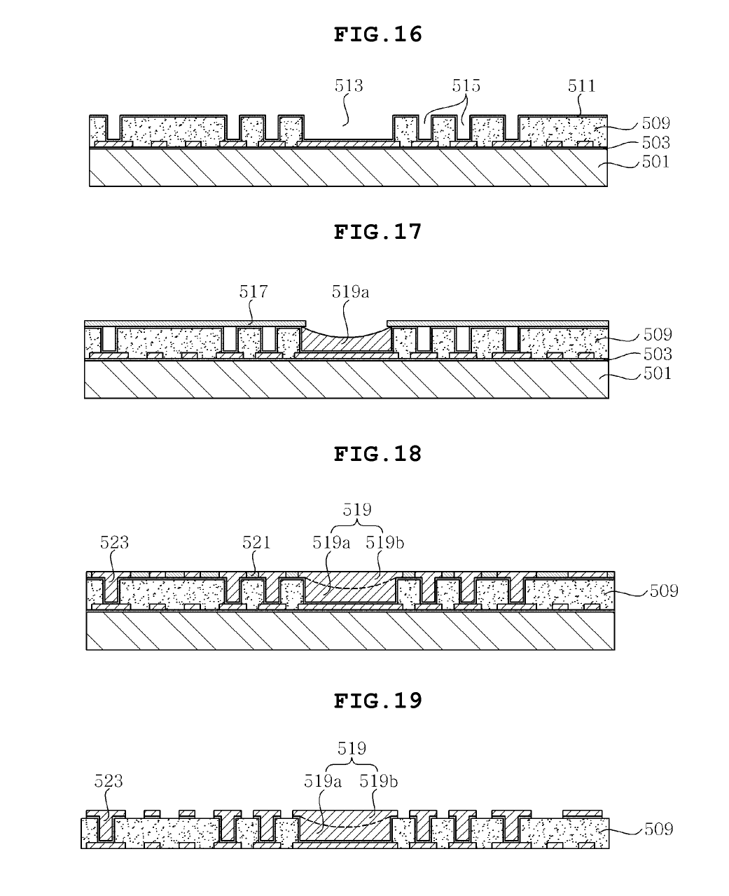

Then, referring to FIG. 18, a plating process is performed on a non-plated region of the via hole 513 for heat radiation, the via hole 515 for signal transfer, and the insulating layer 509 using a conductive metal to thereby form a second circuit layer including connection pads formed on a second plating layer 519b, a signal via 523, and the insulating layer 509.

More specifically, as shown in FIG. 18, a plating resist 521 having an open part is formed on the insulating layer 509 in order to form a circuit layer including the connection pads formed on the heat radiation via 519, the signal via 523, and the insulating layer.

Then, a plating process is performed on the open part using a conductive metal to thereby form the circuit layer including the connection pads formed on the heat radiation via 519, the signal via 523, and the insulating layer 509.

As shown in FIGS. 17 and 18, since the heat radiation via 519 is formed by performing the plating process twice, an interface (a dotted line of FIG. 18) may be formed between the first plating layer 519a by a primary plating process and the second plating layer 519b by a secondary plating process.

Thereafter, the plating resist 521 is removed.

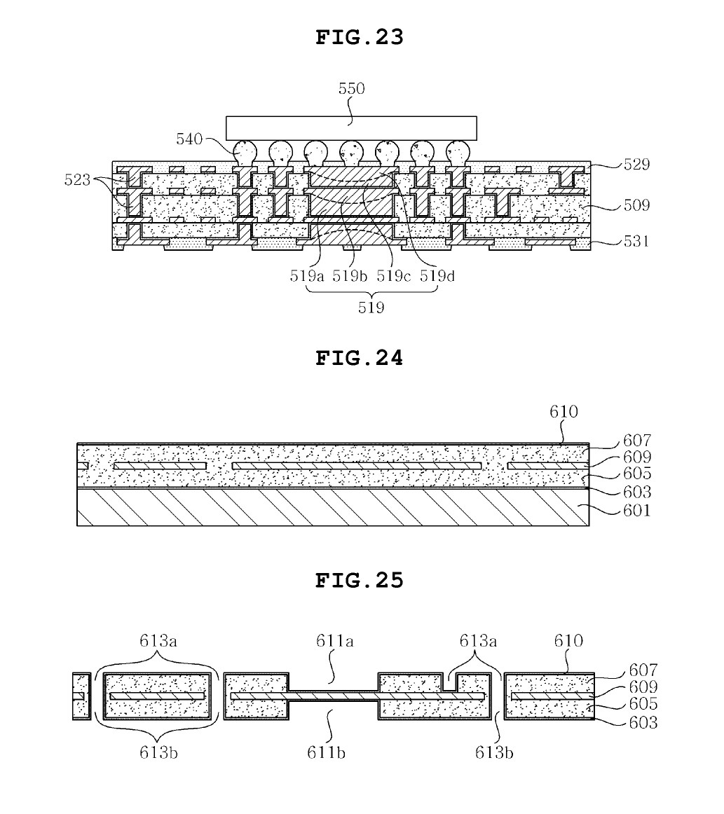

As shown in FIG. 23, when the printed circuit board is a flip chip bonding type, the connection pad may include pads for external connection terminals, and the pads for external connection terminals may include a pad for power or ground and a pad for signal input/output.

The heat radiation via 519 is formed beneath the pad for power or ground, and the signal via 523 is formed beneath the pad for signal input/output.

This should also be reflected at the time of the drilling of the above-mentioned via hole 513 for heat radiation and via hole 515 for signal transfer.

The above-mentioned heat radiation via 519 is positioned so as to efficiently remove heat generated from the pad for power or ground that is expected to generate higher heat, as compared to the pad for signal input/output through which a signal is simply input/output. Therefore, it is possible to stably supply power to the printed circuit board and improve a heat radiation effect of the printed circuit board.

Next, referring to FIG. 19, the carrier member 501 and the seed layer 503 are removed.

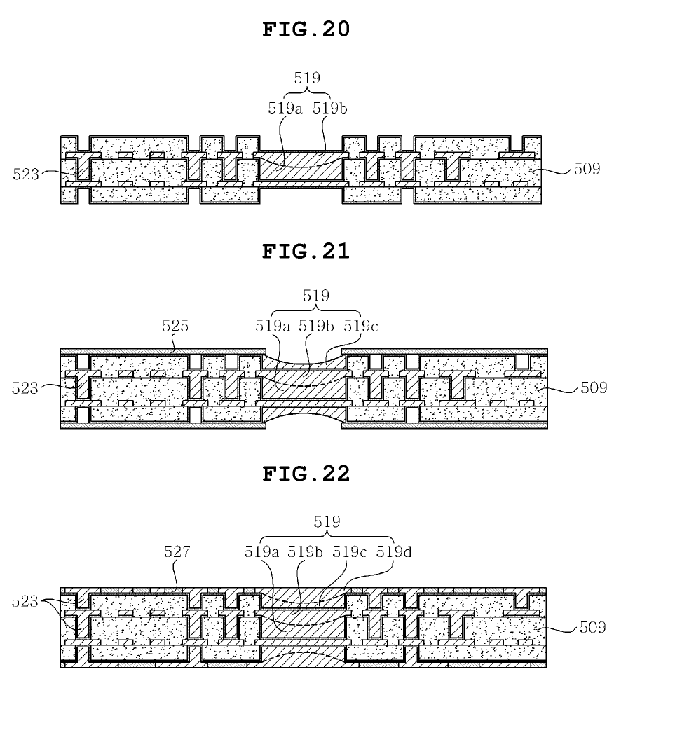

The printed circuit board according to a preferred embodiment of the present invention may be a multi-layer substrate having metal layers for inner layer circuits formed in the insulating layer. Hereinafter, referring to FIGS. 20 to 22, a case in which the printed circuit board is a four-layer substrate will be described by way of example.

Referring to FIG. 20, insulating layers are formed on upper and lower portions of the insulating layer 509 of the printed circuit board in which the carrier member 501 the seed layer 503 are removed in FIG. 19, and a via hole for heat radiation and a via hole for signal transfer are drilled in the insulating layers formed on the upper and lower portions of the insulating layer 509.

Then, referring to FIG. 21, a plating process is performed on the via hole for heat radiation using a conductive metal.

Thereafter, referring to FIG. 22, a plating process is performed on a non-plated region of the via hole for heat radiation, the via hole for signal transfer, and the insulating layer using a conductive metal to thereby form a circuit layer including the connection pads formed on the heat radiation via 519, the signal via 523, and the insulating layer.

Meanwhile, as shown in FIGS. 21 and 22, since the heat radiation via 519 is formed by performing the plating process twice, an interface (a dotted line of FIG. 22) is formed between a first plating layer 519c by a primary plating process and a second plating layer 519d by a second plating process.

Then, as shown in FIG. 23, after the carrier member 501 is removed, a process of forming solder resists 529 and 531 on outermost layers of the printed circuit board and a process of treating a surface are performed and a process of forming external connection terminals 540 for mounting a chip 550 on the pads for external connection terminals is further performed.

Here, when the printed circuit board is the multi-layer substrate for which the process shown in FIGS. 20 to 22 should be performed, the process of forming the solder resists 529 and 531 on the outermost layer of the multi-layer substrate, or the like, should be performed after the carrier member is removed and the multi-layer substrate is completed.

The above-mentioned process of forming solder resists and process of treating a surface are performed in a general scheme. Therefore, a detailed description thereof will be omitted.

### Method Of Manufacturing Printed Circuit Board—Third Preferred Embodiment

FIGS. 24 to 31 are process flowcharts describing a method of manufacturing the printed circuit board of FIG. 3.

However, in a third preferred embodiment, a description for the same components as those of the first and second preferred embodiments will be omitted and a description only for components different therefrom will be provided.

First, referring to FIG. 24, a carrier member 601 having a seed layer 603 formed on one surface thereof is prepared, and a first insulating layer 605 is formed on the carrier member 601.

Then, a metal layer 609 for heat radiation having an open part is formed on the first insulating layer 605, wherein the open part is formed at a region at which a signal via is to be formed. Here, the open part, which is drilled by an etching process, is to form a via hole for signal transfer penetrating through the metal layer 609 for heat radiation.

Next, a second insulating layer 607 and a metal layer 610 are formed on the metal layer 609 for heat radiation.

Here, the metal layer 609 for heat radiation may be made of any one of copper (Cu), aluminum (Al), Invar, and a combination thereof.

The metal layer 609 for heat radiation is inserted into the base substrate formed of an insulating layer at a central point based on a thickness direction thereof and may perform heat radiation in a horizontal direction as well as in a thickness direction of the heat radiation via, thereby further improving heat radiation characteristics of the printed circuit board.

For example, heat generated from the chip is transferred downwardly of the substrate through the heat radiation via. Then, when the heat arrives at the metal layer 609 for heat radiation, a portion thereof is transferred horizontally along the metal layer 609 for heat radiation and the other portion thereof is transferred downwardly of the substrate. Therefore, the heat may be transferred more rapidly, as compared to a case in which the heat is simply transferred in a vertical direction of the substrate.

Then, referring to FIG. 25, the carrier member 601 is removed.

In addition, via holes 613a and 613b for signal transfer and via holes 611a and 611b for heat radiation are formed in the first insulating layer 605, the metal layer 609 for heat radiation, and the second insulating layer 607.

This corresponds to a case in which the insulating layers formed on upper and lower portions of the metal layer 609 for heat radiation are drilled.

That is, according to the present embodiment, the via holes 613a and 613b for signal transfer and the via holes 611a and 611b for heat radiation are formed in a base substrate in which the metal layer 609 for heat radiation and the second insulating layer 607 are formed on the first insulating layer 605.

As shown in FIG. 25, the via holes 613a and 613b for signal transfer have a structure in which they penetrate through or do not penetrate through the metal layer 609 for heat radiation.

However, the via holes 611a and 611b for heat radiation have a structure in which they do not penetrate through the metal layer 609 for heat radiation, which is to uniformly diffuse heat transferred through heat radiation vias also in a horizontal direction through the metal layer 609 for heat radiation, simultaneously with transferring the heat in a thickness direction of the substrate in order to remove heat generated from a chip to be subsequently mounted, thereby further improving a heat radiation effect.

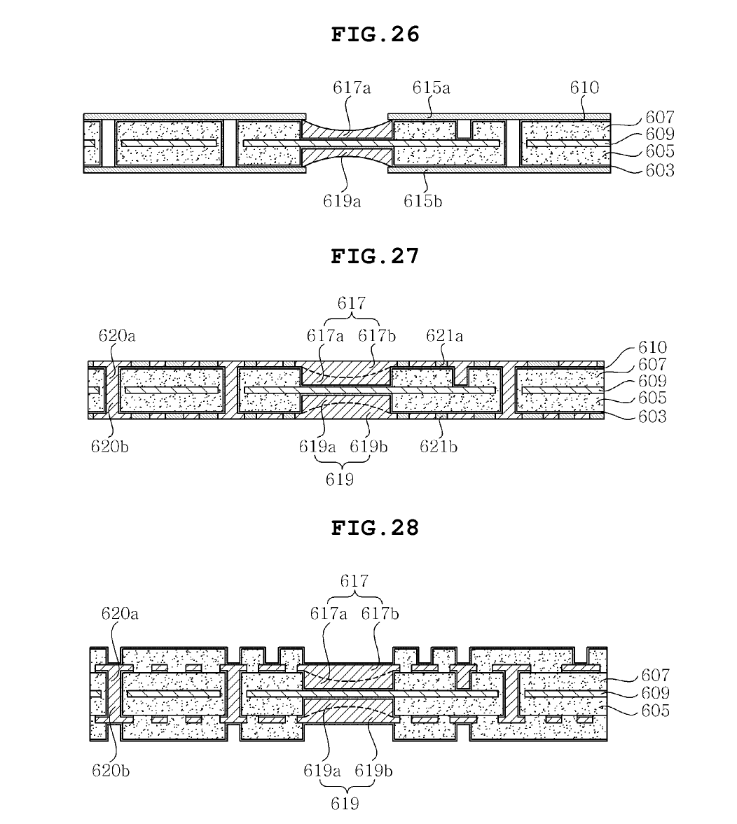

Next, referring to FIG. 26, a plating process is performed on the via holes 611a and 611b for heat radiation using a conductive metal to thereby form first plating layers 617a and 619a.

More specifically, plating resists 615a and 615b having open parts corresponding to the via holes 611a and 611b for heat radiation are formed on the insulating layers 605 and 607.

Here, the open parts may be formed to have diameters smaller than those of the via holes 611a and 611b for heat radiation.

Then, a plating process is performed on the open parts using a conductive metal. Here, the conductive metal is formed to have a height lower than those of upper surfaces of the insulating layers 605 and 607.

Thereafter, the plating resists 615a and 615b are removed.

Next, referring to FIG. 27, a plating process is performed on non-plated regions of the via holes 611a and 611b for heat radiation, the via holes 613a and 613b for signal transfer, and the first and second insulating layers 605 and 607 using a conductive metal to thereby form a circuit layer including connection pads formed on second plating layers 617b and 619b, signal vias 620a, 620b, and the first and second insulating layers 605 and 607.

As shown in FIG. 27, the signal via formed to have a form in which it penetrates through the metal layer 609 for heat radiation of the signal vias 620a and 620b should not contact the metal layer 609 for heat radiation in order to transfer a signal, which should also be reflected at the time of the drilling of the via holes 613a and 613b for signal transfer.

The heat vias 617 and 619 may be formed to have diameters larger than those of the signal vias 620a and 620b in consideration of heat radiation characteristics.

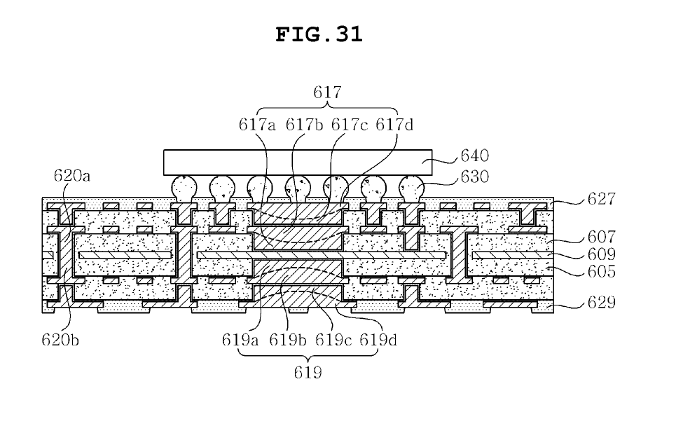

As shown in FIG. 31, when the printed circuit board is a flip chip bonding type, the connection pads may include pads for external connection terminals, and the pads for external connection terminals may include a pad for power or ground and a pad for signal input/output.

In addition, the heat radiation vias 617 and 619 are formed beneath the pad for power or ground, and the signal vias 620a and 620b are formed beneath the pad for signal input/output.

This should also be reflected at the time of the drilling of the above-mentioned via holes 611a and 611b for heat radiation and via holes 613 and 613b for signal transfer.

The printed circuit board according to a preferred embodiment of the present invention may be a multi-layer substrate having metal layers for inner layer circuits formed in the insulating layers. Hereinafter, referring to FIGS. 28 to 30, a case in which the printed circuit board is a multi layer substrate will be described by way of example.

Referring to FIG. 28, insulating layers are formed on the printed circuit board formed in FIG. 27, and via holes for heat radiation and via holes for signal transfer are drilled in the insulating layer.

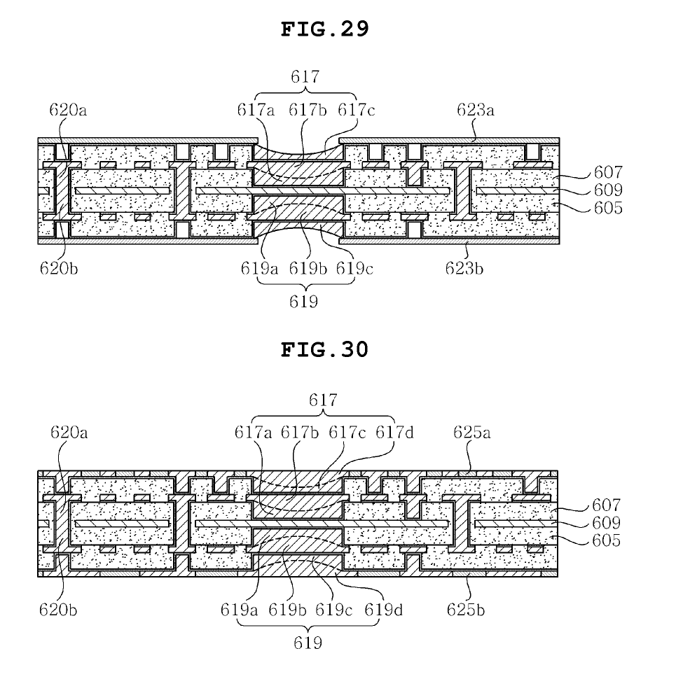

Then, referring to FIG. 29, a plating process is performed on the via holes for heat radiation using a conductive metal.

Thereafter, referring to FIG. 30, a plating process is performed on non-plated regions of the via holes for heat radiation, the via holes for signal transfer, and the insulating layers using a conductive metal to thereby form a circuit layer including the connection pads formed on the heat radiation vias 617 and 619, the signal vias 620a and 620b, and the insulating layers.

Meanwhile, as shown in FIGS. 29 and 30, since the heat radiation vias 617 and 619 are formed by performing the plating process twice, an interface (a dotted line of FIG. 30) is formed between first plating layers 617c and 619c by a primary plating process and second plating layers 617d and 619d by a second plating process.

Then, as shown in FIG. 31, a process of forming solder resists 627 and 629 on outermost layers of the printed circuit board and a process of treating a surface are performed and a process of forming external connection terminals 630 for mounting a chip 640 on the pads for external connection terminals is then further performed.

Here, when the printed circuit board is the multi-layer substrate for which the process shown in FIGS. 28 to 30 should be performed, the process of forming the solder resists 627 and 629 on the outermost layer of the multi-layer substrate, or the like, should be performed after the multi-layer substrate is completed.

The above-mentioned process of forming the solder resists and process of treating a surface are performed in a general scheme. Therefore, a detailed description thereof will be omitted.

With the printed circuit board and the method of manufacturing the same according to the present invention, the heat radiation via and the signal via are implemented to have different sizes, such that the heat radiation via is formed to have a size larger than that of the signal via in a region in which heat radiation is required, thereby making it possible to improve a heat radiation effect.

In addition, according to the present invention, when the heat radiation via and the signal via having different sizes are formed, a plating process is performed twice on the heat radiation via having a size larger than that of the signal via, thereby making it possible to a printed circuit board in which a dimple and a protrusion are not generated on an upper portion of the heat radiation via and the signal via.

Although the preferred embodiments of the present invention have been disclosed for illustrative purposes, they are for specifically explaining the present invention and thus a printed circuit board and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board comprising:
a base substrate having first and second via holes formed therein and having circuit layers formed on both surfaces thereof, the circuit layers including connection pads;
a first via formed in an inner portion of the first via hole and made of a conductive metal; and
a second via formed in an inner portion of the second via hole and including a plurality of plating layers made of a conductive metal,
wherein the second via is formed to have a diameter larger than that of the first via.

2. The printed circuit board as set forth in claim 1, wherein the first and second via holes are a via hole for signal transfer and a via hole for heat radiation, respectively, and
the first and second vias are a signal via and a heat radiation via, respectively.

3. The printed circuit board as set forth in claim 1, wherein a diameter ratio between the first and second vias is 1:2.

4. The printed circuit board as set forth in claim 1, wherein the base substrate is a multi-layer substrate having metal layers for inner layer circuits formed in an insulating layer.

5. The printed circuit board as set forth in claim 1, wherein when the printed circuit board is a wire bonding type, the connection pads include a pad for wire bonding and the circuit layer further includes a pad for chip mounting, and
the second via is formed beneath the pad for chip mounting and the first via is formed beneath the pad for wire bonding.

6. The printed circuit board as set forth in claim 1, wherein when the printed circuit board is a flip chip bonding type, the connection pads include pads for external connection terminals and the pads for external connection terminals include a pad for power or ground and a pad for signal input/output, and
the second via is formed beneath the pad for power or ground and the first via is formed beneath the pad for signal input/output.

7. The printed circuit board as set forth in claim 6, further comprising external connection terminals formed on the pads for external connection terminals in order to mount a chip thereon.

8. The printed circuit board as set forth in claim 7, wherein the external connection terminal is a solder ball.

9. The printed circuit board as set forth in claim 1, wherein the base substrate further includes a metal layer for heat radiation formed in an inner portion thereof.

10. A method of manufacturing a printed circuit board, the method comprising:
preparing a base substrate;
forming first and second via holes in the base substrate;
forming a first plating layer, the first plating layer having a height lower than that of an upper surface of the base substrate by performing a plating process on the second via hole; and
forming a circuit layer including connection pads formed on a second plating layer, a first via, and the base substrate by performing a plating process on a non-plated region of the second via hole, the first via hole, and the base substrate,
wherein the second via includes the first and second plating layers and is formed to have a diameter larger than that of the first via.

11. The method as set forth in claim 10, wherein the first and second via holes are a via hole for signal transfer and a via hole for heat radiation, respectively, and
the first and second vias are a signal via and a heat radiation via, respectively.

12. The method as set forth in claim 10, wherein the preparing of the base substrate includes:
preparing a carrier member having a seed layer formed on one surface thereof;
forming a first circuit layer on the carrier member; and
forming an insulating layer on the first circuit layer.

13. The method as set forth in claim 12, further comprising removing the carrier member after the forming of the circuit layer including the connection pads.

14. The method as set forth in claim 10, wherein the preparing of the base substrate includes:
preparing a carrier member having a seed layer formed on one surface thereof;
forming a first insulating layer on the carrier member;
forming a metal layer for heat radiation having an open part on the first insulating layer, the open part being formed at a region at which the first via is to be formed;
forming a second insulating layer on the metal layer for heat radiation; and
removing the carrier member.

15. The method as set forth in claim 10, wherein the forming of the first plating layer includes:
forming a plating resist on the base substrate, the plating resist having an open part corresponding to the second via hole;
filling the second via hole with a conductive metal through the open part so that the conductive metal has a height lower than that of an upper surface of the base substrate; and
removing the plating resist.

16. The method as set forth in claim 15, wherein the open part is formed to have a diameter smaller than that of the second via hole.

17. The method as set forth in claim 10, wherein the forming of the circuit layer including the connection pads includes:
forming a plating resist having an open part on the base substrate in order to form the circuit layer including the connection pads formed on the second via, the first via, and the base substrate;
forming the circuit layer including the connection pads formed on the second via, the first via, and the base substrate by performing a plating process on the open part; and
removing the plating resist.

18. The method as set forth in claim 10, wherein when the printed circuit board is a wire bonding type, the connection pads include a pad for wire bonding and the circuit layer further includes a pad for chip mounting, and
the second via is formed beneath the pad for chip mounting and the first via is formed beneath the pad for wire bonding.

19. The method as set forth in claim 10, wherein when the printed circuit board is a flip chip bonding type, the connection pads include pads for external connection terminals and the pads for external connection terminals include a pad for power or ground and a pad for signal input/output, and
the second via is formed beneath the pad for power or ground and the first via is formed beneath the pad for signal input/output.

20. The method as set forth in claim 19, further comprising forming external connection terminals on the pads for external connection terminals in order to mount a chip thereon after the forming of the circuit layer including the connection pads.
